(19) United States
(12) Patent Application Publication
(10) Pub. No.: US 2005/0227404 A1
(43) Pub. Date: Oct. 13, 2005

(54) Manufacture of a semiconductor light-emitting device

(76) Inventors: Katherine L. Johnson, Oxford (GB); Stewart E. Hooper, Oxford (GB); Valerie Bousquet, Oxford (GB); Matthias Kauer, Oxford (GB); Jonathan Heffernan, Oxford (GB)

Correspondence Address: MARK D. SARALINO (GENERAL);RENNER, OTTO, BOISELLE & SKLAR, LLP, 1621 EUCLID AVENUE, NINETEENTH FLOOR, CLEVELAND, OH, 44115-2191, US

(21) Appl. No.: 11/082,586

(22) Filed: Mar. 17, 2005

(30) Foreign Application Priority Data
Mar. 18, 2004 (GB) 0406109.9

(51) Int. Cl. H01L 21/461

(52) U.S. Cl. 438/68; 438/93

(57) ABSTRACT

A method of manufacturing a semiconductor light-emitting device is provided. The method includes the step of depositing an electrically conductive material on one or more selected portions of the surface of a semiconductor wafer including a substrate and a layer structure, the layer structure having at least a first semiconductor layer of a first conductivity type and a second semiconductor conductivity layer of a second conductivity type different from the first conductivity type, the first layer being between the second layer and the substrate, such that the electrically conductive material forms a contact to the first semiconductor layer. The method further includes the step of dicing the wafer to form a plurality of light-emitting devices, each light-emitting device having a respective part of the electrically conductive material.

### FIELD OF THE INVENTION

The present invention relates to manufacture of a semiconductor light-emitting device. The method is particularly applicable to manufacture of a light-emitting diode in the (Al,Ga,In)N materials system.

### BACKGROUND OF THE INVENTION

The (Al,Ga,In)N material system includes materials having the general formula AlₓGa_{y}In_{1-x-y}N where 0≦x≦1 and 0≦y≦1. In this application, a member of the (Al,Ga,In)N material system that has non-zero mole fractions of aluminium, gallium and indium will be referred to as AlGaInN, a member that has zero aluminium and indium mole fractions but that has a non-zero mole faction of gallium will be referred to as GaN, and so on.

A light-emitting diode (LED) consists of a semiconductor layer structure grown over a surface of a substrate. The layer structure contains at least one n-type doped layer and at least one p-type doped layer that together provide a p-n junction. Light is generated when an electrical current is passed through the p-n junction. As is common in the manufacture of semiconductor devices, an LED is generally manufactured by growing a semiconductor layer structure over a substrate having a diameter of the order of 5 cm. The resultant product is generally referred to as a “wafer”. The wafer is then cut, or “diced”, to form individual LED chips.

An LED is provided with two electrical contacts to allow a current to be passed through the p-n junction. One contact is generally placed on the layer of the layer structure that is furthest from the substrate (this layer is referred to as the “uppermost” layer or the “surface” layer for convenience) and the other contact is generally provided on the back surface of the substrate (i.e., on the face of the substrate which is opposite to the face on which the layer structure is grown). Thus, the current path from one contact to the other passes through the layer structure in a direction generally perpendicular to the layers of the layer structure and also passes through the substrate.

There is currently particular interest in fabricating LEDs in the (Al,Ga,In)N materials system. LEDs in the (Al,Ga,In)N materials system may emit light in the blue, violet or ultra-violet regions of the spectrum and so have many applications. An (Al,Ga,In)N LED that emits visible light may be used in a colour display or combined with other LEDs to provide a white light source. An (Al,Ga,In)N LED that emits UV light may be used with phosphor materials in a white lighting system.

One problem encountered in fabrication of an LED in the (Al,Ga,In)N system is that sapphire is often used as a substrate for semiconductor devices fabricated in the (Al,Ga,In)N materials system. A sapphire substrate cannot be doped, and so has a high electrical resistance. This prevents the standard vertical LED design, with one contact being deposited on the back face of the substrate, being used for an LED fabricated in the (Al,Ga,In)N materials system on a sapphire substrate—the current path through the LED would have too high an electrical resistance.

FIG. 1 shows a commonly-used structure for an LED grown in the (Al,Ga,In)N materials system on a sapphire substrate 1. A layer structure 4 containing at least an n-type doped layer 2 and a p-type doped layer 3 is grown over the substrate 1—in figure 1(a), the n-type layer 2 is the layer closer to the substrate 1 and the p-type layer 3 is the upper layer of the layer structure. A p-type contact layer 5 is deposited on the exposed surface of the p-type layer 3, and a bond pad 6 is provided on the p-type contact layer 5. A region of the p-type layer 3 that is not covered by the p-type contact layer 5 is etched away to expose the n-type layer 2, and an n-type contact 7 is deposited on the exposed portion of the n-type layer 2. Thus, the current path from the n-contact 7 to the p-contact layer 5, through the junction between the p-type layer 3 and the n-type layer 2, does not pass through the sapphire substrate 1. An (Al,Ga,In)N LED having the general structure shown in FIG. 1(a) is described in U.S. Pat. No. 5,563,422.

This prior art LED structure has the disadvantage that fabrication of an LED requires a large number of processing steps in order to carry out the steps of patterning the p-contact, patterning and etching the n-type layer, and patterning the n-contact. All the patterning steps are conventionally carried out using photolithography.

### ACKNOWLEDGEMENT OF THE PRIOR ART

U.S. Pat. No. 6,281,524 discloses an LED having a similar structure to that shown in FIG. 1(a). It proposes placing a p-type contact pad having a relatively small area on the p-type layer 3 and placing an n-type contact pad having a relatively small area on the exposed part of the n-type layer. A conductive material such as indium is then deposited on the contact pads and down the sides of the layer structure (which have previously been coated with an electrically insulating layer), to form a large area contact. This is said to increase the light output area of the LED by decreasing the electrode area and eliminating the need for a large area bonding pad. However, manufacture of this LED structure involves at least as much photolithography as does manufacture of the LED of FIG. 1(a).

Appl. Phys. Lett, Vol. 66 No. 3 pp 268-270 (1995) describes an LED having a p-n junction formed by an n-type layer 2 and a p-type layer 3 disposed over a sapphire substrate 1. This LED is shown in FIG. 1(b). A p-type contact layer 5 and bond pad 6 are formed on the p-type layer 3 in the same way as in the LED of FIG. 1(a). The n-type contact 7 is also formed on the surface of the p-type layer 3, and penetrates through the p-type layer 3 to make electrical contact with the n-type layer 2. The n-type contact 7 is a “spot” contact—that is, it has a small area when the LED Is seen in plan view.

In manufacture of this LED, the n-type contacts are applied after a wafer has been diced to form individual LED chips. An n-type contact is applied manually to each individual LED chip with a soldering iron. This fabrication technique is therefore completely unsuitable for mass-production. Applying each n-type contact manually to each individual LED chip is extremely costly and time consuming; it also increases the minimum final LED size, which would reduce the yield since fewer LED chips could be made from a wafer of a given area. Furthermore, the electrical properties (I-V curves) shown in this document are poor.

U.S. Pat. No. 5,753,939 discloses a method of manufacturing an LED in the (Al,Ga,In)N material system. In this method, a layer structure is grown which contains, in sequence, an n-type GaN layer, an n-type AlGaN layer, a p-type AlGaN emission layer, a further p-type AlGaN layer, and first and second GaN contact layers. The layer structure is etched to produce a recess that extends downwards through the contact layers, through the p-type AlGaN layers, through the n-type AlGaN layer and into the n-type GaN layer. Nickel is deposited in the recess by vapour deposition, to form the n-contact of the device.

U.S. Pat. No. 5,369,289 discloses a method of manufacturing a light-emitting device in the (Al,Ga)N material system. A layer structure having an i-type GaN layer disposed over an n-type GaN layer is grown, and a recess is formed in the i-type layer to expose the n-type layer. Aluminium is deposited in the recess to form the n-type contact of the device. The process of depositing the aluminium to form the n-type contact involves depositing aluminium over the entire upper surface of the wafer, followed by masking and etching steps to remove aluminium from areas other then where the n-type contact is to be formed.

JP-A-55 009 442 discloses a method of manufacture of a light-emitting device in the GaN material system A layer structure having an i-type GaN layer disposed over an n-type GaN layer is grown, and a recess is formed in the i-type layer to expose the n-type layer. Aluminium is deposited over the entire surface of the wafer by vapour deposition. Nickel or copper film is selectively deposited on the aluminium in the recess, and also at a location where it is desired to provide a p-type contact. The wafer is then dipped in a solder bath to form solder bumps on the nickel or copper film; at the same time, any aluminium not covered by the nickel or copper film is etched away by the solder bath.

JP-A-08 51 235 discloses a method of manufacture of a light-emitting device in the (Al,Ga)N material system. A layer structure having a buffer layer, an n-type cladding layer, a barrier layer, a further cladding layer and a cap layer is grown. The layer structure is partially etched so that part of the buffer layer is exposed. A metal electrode, for example a gold or aluminium electrode, is then deposited by sputtering onto the exposed portion of the buffer layer to form the n-type electrode.

### SUMMARY OF THE INVENTION

A first aspect of the present invention provides a method of manufacturing a semiconductor light-emitting device, the method comprising the steps of, in sequence:
a) depositing an electrically conductive material on one or more selected portions of the surface of a semiconductor wafer comprising a substrate and a layer structure, the layer structure having at least a first semiconductor layer of a first conductivity type and a second semiconductor layer of a second conductivity type different from the first conductivity type, the first layer being between the second layer and the substrate, such that the electrically conductive material forms an electrical contact to the first semiconductor layer, and
b) dicing the wafer to form a plurality of light-emitting devices, each light-emitting device having a respective part of the electrically conductive material.

According to the method of the invention, the contact to the lower layer of the p-n junction (i.e., the layer of the p-n junction nearer the substrate) is made from the upper surface of the device as shown in FIG. 1(b). This avoids the need to provide a contact on the back face of the substrate, and enables a light-emitting device to be fabricated on a high-resistance substrate such as sapphire.

In the invention a contact to the lower layer of the wafer is provided on the wafer, before the wafer has been diced into individual devices. Since the contact is provided on the wafer only one step of providing a contact is required. When the wafer is diced, each device formed in the dicing step will have a respective portion of the contact. The invention eliminates the need to apply a contact individually to each device. The method of the invention is suitable for mass-production.

The invention is particularly of benefit when applied to manufacture of devices in the (Al,Ga,In)N materials system. The invention significantly reduces the processing time and cost of producing LEDs in the (Al,Ga,In)N system when grown on an insulating substrate. The invention may also increase the yield owing to the simpler processing.

Step (a) may comprise melting the electrically conductive material onto the or each selected portion of the surface of the wafer. This enables the contact to be deposited without using any masking, etching or photolithography steps, for example by using a soldering-type technique. The invention is therefore easier to carry out than the conventional methods described above which necessarily involve masking and etching steps.

Step (a) may comprise heating the wafer to a temperature greater than the melting temperature of the electrically conductive material. This is a convenient way of ensuring that the material melts onto the surface of the wafer.

Step (a) may comprise depositing the electrically conductive material on the or each selected portion of the surface of the layer structure and applying heat to the deposited electrically conductive material thereby to melt the deposited electrically conductive material. This is another convenient way of ensuring that the material melts onto the surface of the wafer.

The method may comprise melting the electrically conductive material onto the or each selected portion of the surface of the wafer so that the melted electrically conductive material penetrates through the second semiconductor layer to the first semiconductor layer.

The electrically conductive material may have a melting point of 400° C. or below. This allows the electrically conductive material to be deposited by a “soldering-type” technique in which the electrically conductive material is melted onto the or each selected portion of the surface of the wafer. As explained above, this enables the contact to be deposited without using any masking, etching or photolithography steps. In contrast, the prior art methods in which the n-type electrode is deposited by vapour deposition or sputtering necessarily entail masking, etching or photolithography steps.

Alternatively, step (a) may comprise forming one or more grooves in surface of the wafer and depositing the electrically conductive material onto the or each selected portion of the surface of the wafer and into the or each groove. This increases the adhesion between the material and the wafer.

The or each groove may extend through the complete thickness of the second semiconductor layer so as to expose the first semiconductor layer. This allows the electrically conductive material to make contact with the first semiconductor layer, and this improves the electrical characteristics of the resultant device.

The or each portion of the surface of the layer structure may be linearly extending.

The electrically conductive material may be deposited in a plurality of strips such that each device formed in step (b) comprises respective parts of at least two different strips of the electrically conductive material. This can reduce current crowding effects in the resultant device.

A second aspect of the present invention provides a method of manufacturing a semiconductor light-emitting device comprising the steps of, in sequence:
a) exposing one or more selected regions of a first semiconductor layer in a semiconductor wafer comprising a substrate and a layer structure, the layer structure having at least a first semiconductor layer of a first conductivity type and a second semiconductor layer of a second conductivity type different from the first conductivity type, the first layer being between the second layer and the substrate, and depositing an electrically conductive material having a melting point of 400° C. or below directly on the one or more exposed portions of the first semiconductor layer thereby to form an electrical contact to the first semiconductor layer; and
b) dicing the wafer to form a plurality of light-emitting devices, each light-emitting device having a respective part of the electrically conductive material.

Again, the use of an electrically conductive material with a melting point of 400° C. or below allows the electrically conductive material to be deposited by a “soldering-type” technique in which the electrically conductive material is melted onto the or each selected portion of the surface of the wafer.

The electrically conductive material may have a melting point of 350° C. or below, or even a melting point of 300° C. or below. This makes it easier to use a soldering-type technique to deposit the electrically conductive material. In general, the lower the melting point of the electrically conductive material, the easier it will be to use a soldering-type technique to deposit the electrically conductive material.

Step (a) may comprise melting the electrically conductive material onto the or each exposed portion of the first semiconductor layer.

Step (a) may comprise heating the wafer to a temperature greater than the melting temperature of the electrically conductive material.

Step (a) may comprise depositing the electrically conductive material on the or each exposed portion of the first semiconductor layer and applying heat to the deposited electrically conductive material thereby to melt the deposited electrically conductive material.

The method may comprise the step of annealing the wafer after step (a) and before step (b).

The electrically conductive material may be a metal. It may be indium.

The method may comprise the further step of providing a plurality of contacts to the second semiconductor layer on the wafer such that each light-emitting device obtained in step (b) comprises a respective one of the contacts to the second semiconductor layer.

The step of forming the plurality of contacts to the second semiconductor layer may be carried out before step (a). If the contacts are formed in this order, the contacts to the first semiconductor layer will not interfere with any masks used in the deposition of the contacts to the second semiconductor layer.

The method may comprise the step of fabricating the semiconductor wafer by depositing a semiconductor layer structure over a substrate, the layer structure including at least a first semiconductor layer having a first conductivity type and a second semiconductor layer having a second conductivity type different from the first conductivity type.

The first semiconductor layer may be a (Al,Ga,In)N layer. The second semiconductor layer may be a (Al,Ga,In)N layer.

The substrate may be a sapphire substrate.

A third aspect of the present invention provides a semiconductor light-emitting device manufactured by a method of the first or second aspect.

### BRIEF DESCRIPTION OF THE DRAWINGS

Preferred embodiments of the present invention will be described by way of illustrative example with reference to the accompanying drawings in which:

FIG. 1(a) is a schematic sectional view of one known LBD structure;

FIG. 1(b) is a schematic sectional view of another known LED structure;

FIGS. 2 and 3 show electrical properties of an LED of the present invention;

FIG. 4(a) is a schematic plan view of an LED array on a wafer made by a method of the present invention;

FIG. 4(b) is a schematic plan view of an LED chip obtained from the wafer of FIG. 4(a);

FIG. 5 shows an individual mounted LED made by a method of the present invention;

FIGS. 6(a) and 6(b) illustrate steps in manufacture of an LED of the present invention, and FIG. 6(c) is a sectional view through an LED of the present invention;

FIG. 7(a) is a schematic plan view of an LED array on a wafer made by another method of the present invention;

FIG. 7(b) is a schematic plan view of an LED chip obtained from the wafer of FIG. 7(a);

FIG. 8(a) is a schematic plan view of an LED array on a wafer made by another method of the present invention;

FIG. 8(b) is a schematic plan view of an LED chip obtained from the wafer of FIG. 8(a);

FIG. 9(a) is a schematic plan view of an LED array on a wafer made by another method of the present invention;

FIG. 9(b) is a schematic plan view of an LED chip obtained from the wafer of FIG. 9(a); and

FIGS. 10(a) to 10(d) illustrate a method according to another embodiment of the invention.

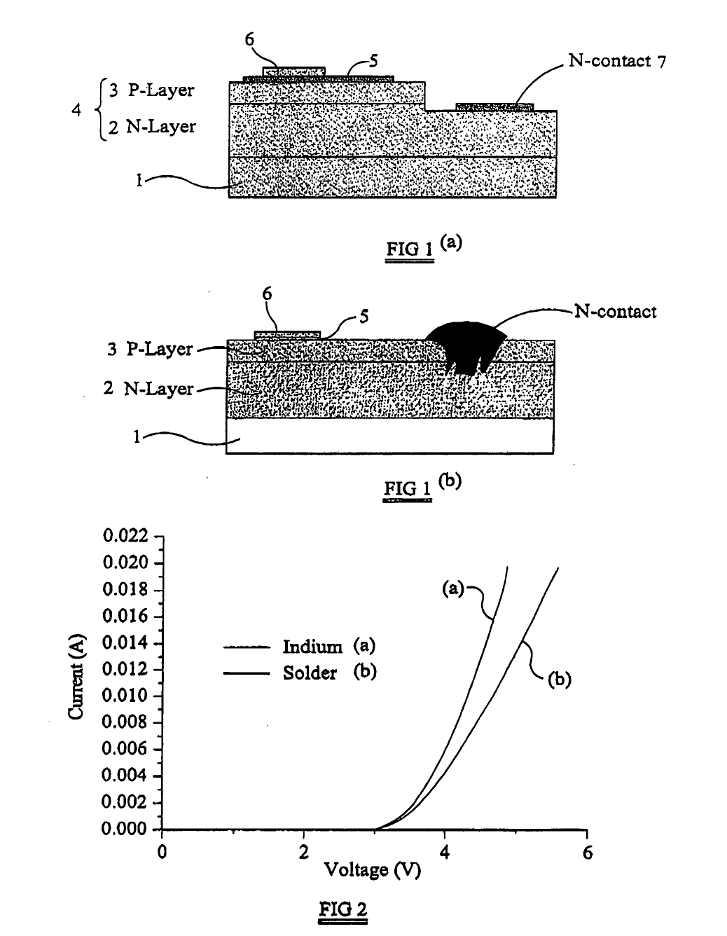

### DETAILED DESCRIPTION OF THE PREFERRED EMBODIMENTS

The invention will be described with reference to manufacture of an LED in the (Al,Ga,In)N materials system on a sapphire substrate. However, the invention is not limited to this specific application. Like reference numerals denote like components throughout the drawings.

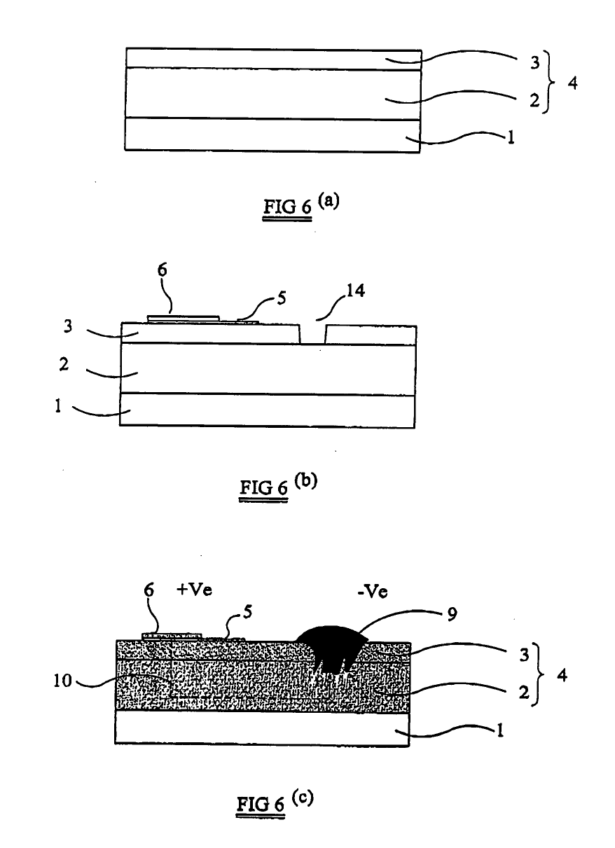

Initially, a semiconductor layer structure 4 is grown over a substrate 1, as shown in FIG. 6(a). The layer structure contains at least a first semiconductor layer 2 having a first conductivity type (for example an n-type layer) and a second semiconductor layer 3 having a second conductivity type different from the first conductivity type (for example a p-type layer), with the first layer being disposed between the second layer and the substrate. Thus, the layer structure contains a junction between materials of different conductivity type, for example a p-n junction. Light is emitted when an electrical current is passed through the junction.

In a preferred embodiment the layer structure consists of a plurality of layers of GaN, InGaN, AlGaN and/or AlGaInN, and is grown over a sapphire substrate. The structure comprises, in sequence: one or more n-type doped layers that are either disposed adjacent to the substrate or separated from the substrate by an region that is not intentionally doped; an active region, which may or may not contain intentionally-doped layers; and one or more p-type doped layers. Thus, the layer of the layer structure that is furthest away from the substrate (this will be referred to as the “surface layer”) is doped p-type in this embodiment. As is conventional in the growth of (Al,Ga,In)N materials, n-type doping may be achieved by doping with silicon, germanium, selenium, sulphur or tellurium and p-type doping may be achieved by doping with magnesium, carbon, beryllium, strontium, barium or zinc. Thus a p-n junction is formed with a quantum well region at the junction, and this may be electrically driven to emit light.

The details of the layer structure are not important for the invention, and any suitable layer structure may be used. The method of the invention is not limited to the (Al,Ga,In)N materials system nor to a sapphire substrate. The details of the growth process are again not important for the invention, and any suitable growth technique may be used.

As is conventional, the substrate used in the growth process has a diameter of the order of 5 cm. Growing the layer structure over the substrate produces a wafer having the same diameter as the substrate; the wafer will ultimately be diced to form individual LED chips.

Before the wafer is diced, electrical contacts arc provided on the wafer. FIG. 4(a) is a schematic plan view of a wafer, which will be diced to form a number of LED chips (nine LED chips are indicated in FIG. 4(a), although in practice a wafer will be diced to form many more than nine LED chips). FIG. 4(a) shows the wafer 8 after p-contacts 5 and strips of conductive material 11a-11c that will provide the n-contacts have been formed. FIG. 4(b) is an enlarged partial view of FIG. 4(a) showing the area of a wafer corresponding to a single LED chip.

The p-contacts shown in FIGS. 4(a), 4(b) and 6(c) are conventional p-type contacts. Each p-contact comprises a contact layer 5 on which is disposed a p-contact bond pad 6. The contact layer 5 is preferably transparent to light emitted by the LED (where transparent is defined as transmitting more than 1% of the light emitted by the LED). The p-contacts may be deposited using conventional masking or photolithography methods. They may be annealed, for example in a Rapid Thermal Annealer at 520° C. for 5 minutes. One p-type contact layer 5 is provided for each LED chip that is intended to be formed when the wafer 8 is diced.

The n-type contacts 9 are provided by depositing an electrically conductive material on one or more selected portions of the surface of the wafer 8 such that the electrically conductive material melts onto the surface of the wafer thereby to form an electrically conductive path to the n-type semiconductor layer 2. The melted electrically conductive material may penetrate into the p-type layer 3, and preferably penetrates through the p-type layer 3 and into the n-type layer 2 as shown in FIG. 6(c).

In a preferred embodiment of the invention a groove or scratch 14 is formed in the p-type layer 3 along the intended position of an n-type contact 9, as shown in FIG. 6(b). In a particularly preferred embodiment the groove is made deep enough to expose the n-type layer 2, as this has been found to provide improved electrical characteristics of the final device by allowing the material of the n-type contact to make direct contact to the n-type layer. Providing a groove 14 along the intended position of an n-type contact 9 may also improve the adhesion between the n-type contact and the wafer, and so improve the reliability of the device. After the groove 14 has been formed, the electrically conductive material 9 is deposited in the groove 14 and over regions of the surface of the wafer adjacent to the groove, as shown in FIG. 6(c).

In a preferred embodiment the groove is formed using a mechanical process, for example by scratching the surface of the wafer. This has the advantage that the formation of the groove does not require any mask, etching or photolithography steps.

The width of a groove may in principle be made as small as the technique used to form the groove will allow. In principle there is no upper limit on the width of a groove, but making the grooves very wide will increase the size of each LED and so reduce the number of LBDs that can be produced from one wafer. The width of a groove 14 is typically in the range from 10 μm to 1 mm.

Although it is preferred to from a groove in the p-type layer 3 along the intended position of an n-type contact 9 so as to expose the n-type layer, it has been found that the step of forming the groove may be omitted and that invention may be carried out simply by depositing the conductive material on the surface of the p-type layer along the intended position of an n-type contact. Alternatively, a groove that is not deep enough to expose the n-type layer may be formed in the p-type layer along the intended position of an n-type contact.

One of the characteristics of the (Al,Ga,In)N materials system is the low maximum p doping that can be achieved. This results in the p-type layer 3 having a greater electrical resistivity than the n-type layer 2. Thus, while a current path does exist from the n-type contact 9 to the p-type contact pad 6 via the p-type layer 3 in the LED of FIG. 6(c), this current path has a significantly higher resistance that the current path 10 shown in FIG. 6(c) from the n-type contact 9 to the p-type contact pad 6 via the n-type layer 2. The current path 10 is therefore the dominant current path when the LED is in operation.

According to the invention, the n-type contact is formed by depositing the electrically conductive material on the wafer before the wafer is diced so that, when the wafer 8 is diced, the material forms the n-type contact for more than one LED chip. In the embodiment of FIG. 4(a) the electrically conducive material is deposited on the wafer 8 in three strips 11a, 11b, 11c which are approximately parallel to one another.

When the wafer 8 is diced, each strip of electrically conductive material is cut so as to form the n-type contact for more than one LED chip (each strip is cut so as to form the n-type contact for three LED chips in the example of FIG. 4(a)). For example, when the wafer 8 of FIG. 4(a) is diced each LED chip obtained from the central column of LED structures has an n-contact formed of a portion of the central strip 11b of conductive material.

The present invention thus eliminates the need to apply an individual n-contact to each LED chip after the wafer has been diced. Each conductive strip that is provided on the wafer will form the n-contact for a plurality of LEDs.

In principle, the material used to form the n-type contact may be applied onto the wafer, and into the groove 14 if provided, by any suitable technique. However, it is preferable if the material of the n-contact is applied directly onto those parts of the surface of the wafer, and into the groove 14 if present, where it is desired to form the contact. This enables the n-contact to be deposited on the wafer 8 without the need for any masking or etching steps. This allows the invention to be applied in a mass-production technique. This embodiment of the invention thus provides a quick, cheap and easy method of producing LEDs on an insulating substrate and, in particular, may be applied to mass-production of LEDs in the (Al,Ga,In)N materials system.

One way of applying the n-contact directly onto the wafer is to deposit a metal having a low melting point, such as indium or solder, onto the wafer using a metal probe (or “tip”). Where the material used to form the n-type contact is a low melting temperature metal, the material of the n-contact may be applied onto a wafer that is at room temperature, with the heat required to melt the material of the n-contact being supplied by the probe or tip that is applying the material. The metal to form the contact is initially solid, and is melted against the heated probe onto the surface of the wafer in a soldering-type technique, with the probe acting as the tip of a soldering iron. Alternatively, the material of the n-contact may be applied to a wafer that is heated to a temperature above the melting temperature of the material, and is applied with a tip which is not independently heated. As a yet further alternative, the material of the n-contact may be applied to a wafer that is heated above room temperature via a tip that is independently heated above room temperature.

In general, use of a soldering-type technique or one of the other techniques described above requires that the metal used for the n-type contact has a melting point of no more than approximately 400° C., and preferably has a melting point of no more than approximately 350° C. or even no more than approximately 300° C. Suitable metals with a melting point below 400° C. include indium and many solders (for the avoidance of doubt, the term “metal” as used herein includes alloys).

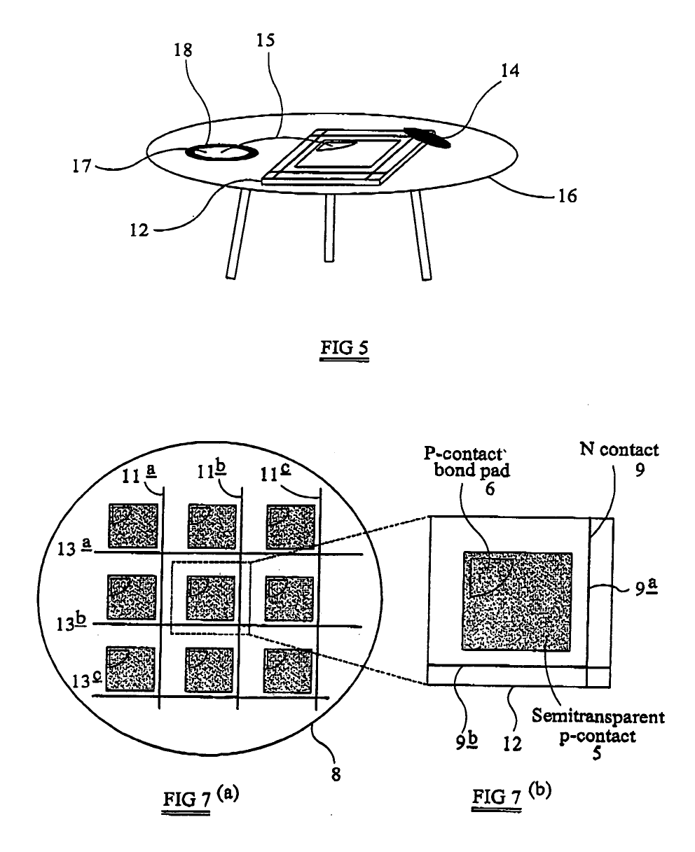

Once the n- and p-contacts have been provided on the wafer 8, the wafer is diced to leave a p-contact 5,6 and a stripe of conductive material that forms an n-contact on each LED chip 12 formed in the dicing step. One LED chip formed in the dicing step is shown in FIG. 4(b). Each LED chip 12 is then mounted on a header 16 as shown in FIG. 5. Electrically conductive material 14 is applied to short the n-contact 9 of the chip to the base of the header. An external lead 15, which is connected to a region 17 of the header base that is electrically insulated from the remainder of the header base by an insulator 18, is bonded to the bond pad 6 of the p-type contact.

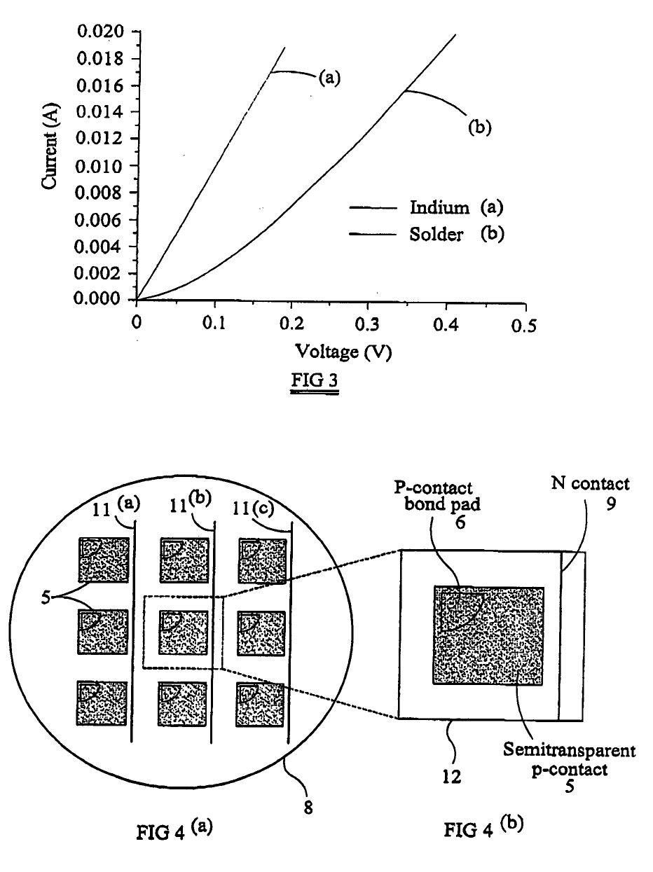

FIGS. 2 and 3 show electrical properties of an LED chip manufactured by the method of the present invention. FIG. 2 shows current-voltage characteristic curves for an LED chip provided with an indium n-type contact (curve a) and a solder n-type contact (curve b). It will be seen that both curves display good diode characteristics.

FIG. 3 shows current-voltage characteristic curves measured from one n-contact to another n-contact on a wafer before dicing, again for indium n-type contacts (curve a) and solder n-type contacts (curve b). It will be seen that the contacts exhibit good ohmic behaviour, particularly the indium contacts. The characteristic curves also show that the devices have a low electrical resistance.

In a further embodiment of the invention the wafer is annealed after the n contact has been deposited on the wafer. The wafer may be annealed after deposition of the n-contact in a furnace or a Rapid Thermal Annealer. As is well known, contacts to semiconductor layers are often annealed to improve their electrical characteristics. The effect of annealing is to, for example, promote surface doping (due to diffusion of surface atoms into the contact or contact atoms into the surface), annealing out of impurities, or improving the contact. In one embodiment a device of the invention was annealed in a Rapid Thermal Annealer that could provide a temperature of between 200° C. and 1000° C., for an annealing time of between 1 second and 1 hour. Annealing the n-type contact at an annealing temperature of 520° C. for 5 minutes was found to provide good results.

In the embodiment described above the n-type contacts are formed after the p-type contacts have been deposited on the wafer. Conventional techniques for forming the p-type contacts involve etching/photolithography steps that involve use of masks. Forming the n-type contacts after the p-type contacts have been formed prevents the n-type contacts from interfering with any masks used in the deposition of the p contacts. Also, in this embodiment only one annealing step is required, as the p-type contacts are present during the step of annealing the n-type contacts and so are annealed when the n-type contacts are annealed.

A further advantage of the invention is that it can also give a higher yield owing to the simpler processing required.

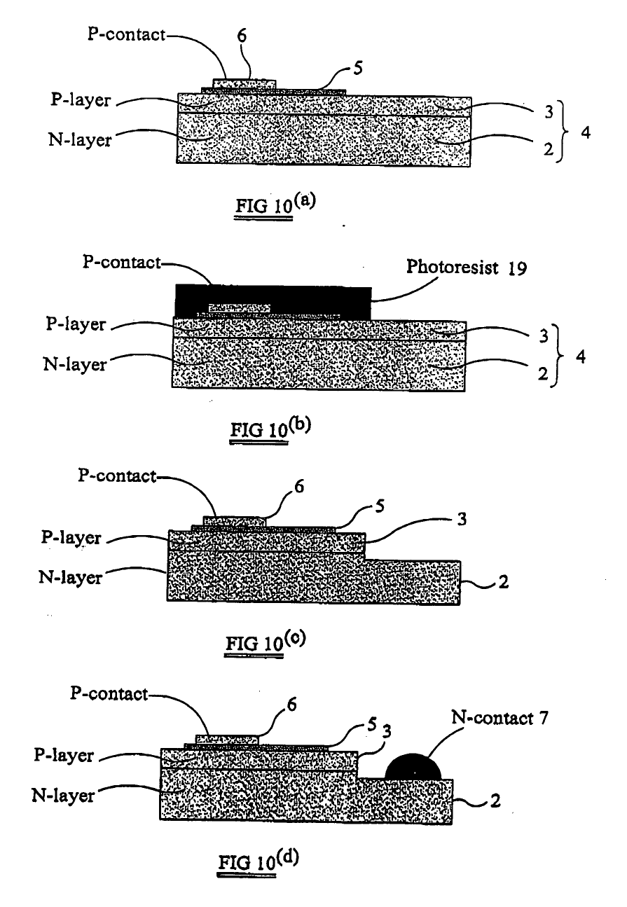

In a further embodiment of the invention, the n-contacts are formed on the wafer by etching a region of the wafer to reveal an n-type layer and the n-contacts are applied directly to the n-type layer. Principal steps of the method of this embodiment are shown in FIGS. 10(a) to 10(d).

Initially, a semiconductor layer structure 4 containing semiconductor layers of two different conductivity types is grown. The semiconductor layer structure 4 is shown schematically in FIG. 10(a), and only the surface semiconductor layer 3 and an underlying semiconductor layer 2 are shown. It should be noted, however, that the layer structure would in practice be grown on a substrate, and would possibly contain further semiconductor layers. A plurality of contacts to the surface layer are provided on part of the upper surface of the surface layer 3 (for simplicity of description only one contact is shown). In this embodiment the surface layer 3 is a p-type layer, the underlying layer 2 is an n-type layer, and each contact is a p-type contact formed of a contact layer 5 and a bond pad 6.

Next, the semiconductor layer structure is etched to form at least one mesa structure. This may be done by depositing a photoresist 19 over parts of the layer structure that are not to be etched. The regions of the layer structure where the p-contacts are provided should not be etched, so photoresist 19 is disposed over each p-type contact as indicated in FIG. 10b). The semiconductor layer structure is then etched using any convenient etching technique, and the photoresist is removed. FIG. 10(c) shows the semiconductor layer structure after the etching step has been carried out and the photoresist has been removed.

Next, an n-type contact 7 is disposed on the exposed portion(s) of the n-type layer. The n-type contact 7 is disposed in the form of one or more strips; for example the n-type contact 7 may be formed of a number of strips arranged in a similar manner to the strips 11a,11b,11c shown in FIG. 4(a). (Again, for simplicity of description, only one n-type contact strip is shown in FIG. 10(d)). The n-type contact 7 is provided by depositing an electrically conductive material on the exposed portion(s) of the n-type layer such that the electrically conductive material melts onto the surface of the layer; the material may be deposited by any of the methods described above. The n-type layer may or may not be scored to form a groove before the n-contact is deposited. FIG. 10(d) shows the semiconductor layer structure after the n type contact 7 has been deposited.

The semiconductor layer structure is then diced to form individual LED chips. As in the previous embodiments the semiconductor layer structure is diced such that each chip contains one p-type contact and a part of the n-typo contact.

In this embodiment etching or photolithography steps are used to define a mesa structure in the wafer. However, formation of the n-type contacts by the method of the invention means that no etching, masking or photolithography steps are required to form the n-type contacts.

The invention has been thus far described with reference to the embodiment of FIGS. 4(a) and 4(b), in which the n-contact is applied to the wafer as a series of non-intersecting stripes. One stripe 11a,11b,11c is provided for each column (or alternatively for each row) of LEDs on the wafer. When the wafer is diced, each LED chip has an n-contact in the form of (in plan view) a strip as shown in FIG. 4(b).

In the LED chip shown in FIG. 4(b), the contact pad 6 of the p-contact is disposed near a corner of the p-contact layer 5 and so is close to two sides of the LED chip and is spaced from the other two sides of the LED chip. The n-contact preferably extends along, or near to, a side of the LED chip that is spaced from the contact pad 6 of the p-contact, since this provides a more even distribution of current over the area of the LED chip and so eliminates or reduces current crowding effects that could occur if the n-contact were to extend along a side of the LED chip close to the contact pad 6 of the p-contact.

The invention is not, however, limited to the formation of n-contacts of the particular form shown in FIGS. 4(a) and 4(b). For example, in the embodiment illustrated in FIGS. 7(a) and 7(b) the n-contact is applied to the wafer 8 in the form of two sets of strips 11a,11b,11c; 13a,13b,13c. The strips 11a,11b,11c of one set arc crossed with and intersect the strips 13a,13b,13c of the other set. The strips of the first set are generally parallel to one another and are provided one for each column of LEDs on the wafer. The strips of the second set arc generally parallel to one another and are provided one for each row of LEDs on the wafer. Each strip 11a-11c,13a-13c may be applied by a method as described above.

When the wafer is diced into LED chips each LED chip has an n-contact 9 that consists of, as shown in FIG. 7(b), a first segment 9a and a second segment 9b. The two segments of the n-contact of an LED chip intersect one another and are electrically connected together at their intersection so as to provide a single continuous contact. This provides a more even distribution of current over the area of the LED, and reduces current crowding effects.

In the embodiment of FIGS. 7(a) and 7(b), the strips 11a,11b,11c; 13a,13b,13c of n-contact material are preferably applied to the wafer 8 such that, when the wafer is diced, the two segments 9a,9b of the n-contact of an LED chip 12 extend along, or near, the two sides of the LED chip 12 that are furthest from the bond pad 6 of the p-contact. This is particularly effective at reducing current crowding effects.

FIGS. 8(a) and 8(b) illustrate another embodiment of the invention. In this embodiment the n-contact material is applied to the wafer in two sets of strips 11a,11b,11c;13a-13f. The strips 11a,11b,11c of one set intersect the strips 13a-13f of the other set. The strips of the first set are generally parallel to one another and are provided one for each column of LEDs on the wafer. The strips of the second set are generally parallel to one another, and two strips of the second set are provided for each row of LEDs on the wafer. The two strips of the second set for a row of LEDs on the wafer are positioned on opposite sides of the p-contact of the LEDs in the row. For example, strips 13a and 13d extend below and above, respectively, the upper row of LEDs on the wafer 8. Each strip 11a-11c, 13a-13f may be applied by a method as described above.

When the wafer is diced into LED chips each LED chip produced has an n-contact 9 that consists of, as shown in FIG. 8(b), a first segment 9a, a second segment 9b and a third segment 9c. The second and third segments 9b,9c each intersect, and so are electrically connected to, the first segment 9a so as to provide a single continuous n-contact. The resultant n-contact 9 extends substantially along, or near to three sides of the LED, and this provides a more even distribution of current over the area of the LED chip and reduces current crowding effects.

In the embodiment of FIGS. 8(a) and 8(b), the bond pad 6 of the p-contact is preferably positioned approximately midway along on side of the p-contact layer 5 rather than in a corner of the p-contact layer 5. The segments 9a, 9b, 9c of the n-contact extend along, or near to, the three sides of the p-contact layer that are furthest from the bond pad 6. Positioning the bond pad of the p-contact in this way, rather than near one corner of the p-contact 5, further minimises current crowding effects.

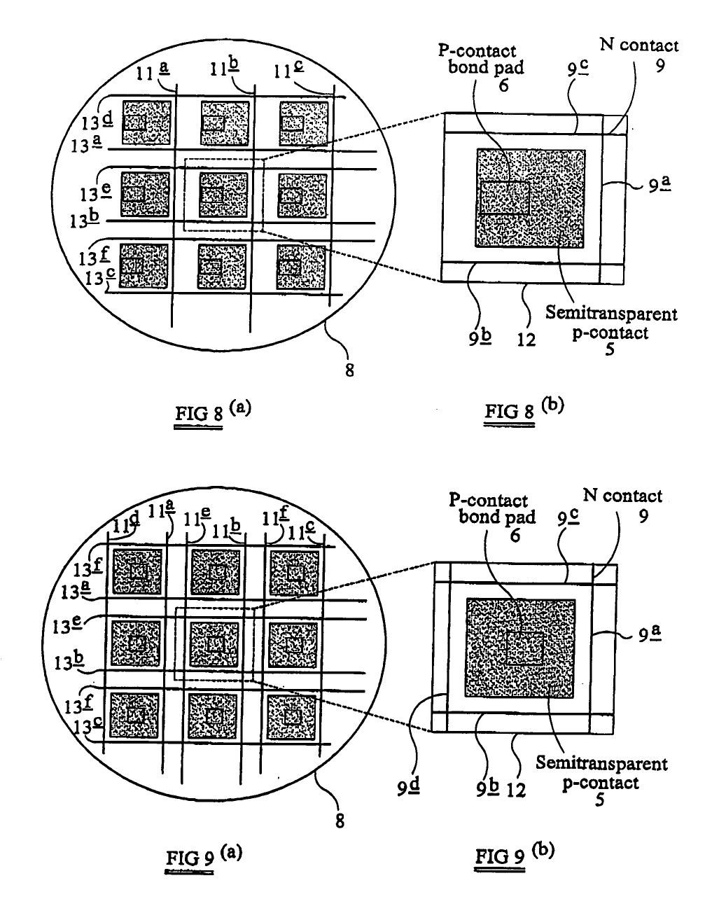

FIGS. 9(a) and 9(b) illustrate another embodiment of the invention. In this embodiment the n-contact material is applied to the wafer 8 in the form of two sets of strips 11a-11f;13a-13f. The strips 11a-11f of one set intersect the strips 13a-13f of the other set. The strips of the first set are generally parallel to one another and two are provided for each column of LEDs on the wafer. For each column of LEDs on the wafer, the two strips of the first set for that column are positioned on opposite sides of the p-contacts of the LED chips in the column. The strips 13a-13f of the second set are generally parallel to one another, and two strips of the second set are provided for each row of LED chips on the wafer. For each row of LED chips on the wafer the two strips of the second set for a row are positioned on opposite sides of the p-contacts of the LED chips in the row. For example, strips 13a and 13d extend below and above, respectively, the upper row of LEDs on the wafer 8. Each strip 11a-11f, 13a-13c may be applied by a method as described above.

When the wafer is diced into LED chips each LED chip has an n-contact 9 that consists of, as shown in FIG. 9(b), a first segment 9a, a second segment 9b, a third segment 9c and a fourth segment 9d. The second and third segments 9b,9c intersect, and so are electrically connected to, each of the first segment 9a and the fourth segment 9d so as to provide a single continuous n-contact. The resultant n-type contact extends substantially along, or near to, all four sides of the LED chip, and this provides a more even distribution of current over the area of the LED chip 12 and reduces current crowding effects.

In the embodiment of FIGS. 9(a) and 9(b), the bond pad 6 of the p-contact is preferably positioned approximately centrally on the p-contact 5. Positioning the bond pad 6 of the p-contact here, rather than near one corner of, or near one side, of the p-contact 5, further minimises current crowding effects.

As explained above the material used for the n-contact is preferably a metal having a low melting temperature, in particular a metal having a melting temperature of 400° C. or lower, and preferably 350° C. or lower, to allow use of a soldering-type technique to deposit the n-type contact. Suitable metals for the n-contact include indium, tin, lead, gallium, lithium, selenium, bismuth, thallium, zinc or tellurium. Alloys of these materials, such as a solder, may also be used.

In the embodiments described above the n-contact material has been applied to the wafer 8 in strips that are substantially straight, and this leads to an LED chip with an n-contact that is substantially straight or that is composed of substantially straight segments. Applying the n-contact material to the wafer 8 in strips that are substantially straight is generally preferred for ease of deposition of the n-contact material, but in principle the n-contact material need not be applied to the wafer 8 in straight strips.

1. A method of manufacturing a semiconductor light-emitting device comprising the steps of, in sequence:
a) depositing an electrically conductive material on one or more selected portions of the surface of a semiconductor wafer comprising a substrate and a layer structure the layer structure having at least a first semiconductor layer of a first conductivity type and a second semiconductor layer of a second conductivity type different from the first conductivity type, the first layer being between the second layer and the substrate, such that the electrically conductive material forms a contact to the first semiconductor layer; and
b) dicing the wafer to form a plurality of light-emitting devices, each light-emitting device having a respective part of the electrically conductive material.

2. A method as claimed in claim 1 wherein step (a) comprises melting the electrically conductive material onto the or each selected portion of the surface of the wafer.

3. A method as claimed in claim 2 wherein step (a) comprises heating the wafer to a temperature greater than the melting temperature of the electrically conductive material.

4. A method as claimed in claim 2 wherein step (a) comprises depositing the electrically conductive material on the or each selected portion of the surface of the wafer and applying heat to the deposited electrically conductive material thereby to melt the deposited electrically conductive material.

5. A method as claimed in claim 1 wherein step (a) comprises melting the electrically conductive material onto the or each selected portion of the surface of the wafer so that the melted electrically conductive material penetrates into the first semiconductor layer.

6. A method as claimed in claim 1 wherein the electrically conductive material has a melting point of 400° C. or below.

7. A method as claimed in claim 1 wherein step (a) comprises: forming one or more grooves in surface of the wafer; and depositing the electrically conductive material onto the or each selected portion of the surface of the wafer and into the or each groove.

8. A method as claimed in claim 7 wherein the or each groove extends through the complete thickness of the second semiconductor layer so as to expose the first semiconductor layer.

9. A method as claimed in claim 1 wherein the or each portion of the surface of the wafer is linearly extending.

10. A method as claimed in claim 1 wherein the electrically conductive material is deposited in a plurality of strips such that each device formed in step (b) comprises respective parts of at least two different strips of the electrically conductive material.

11. A method of manufacturing a semiconductor light-emitting device comprising the steps of, in sequence:
a) exposing one or more selected regions of a first semiconductor layer in a semiconductor wafer comprising a substrate and a layer structure, the layer structure having at least the first semiconductor layer of a first conductivity type and a second semiconductor layer of a second conductivity type different from the first conductivity type, the first layer being between the second layer and the substrate, and depositing an electrically conductive material having a melting point of 400° C. or below directly on the one or more exposed portions of the first semiconductor layer thereby to form an electrical contact to the first semiconductor layer; and
b) dicing the wafer to form a plurality of light-emitting devices, each light-emitting device having a respective part of the electrically conductive material.

12. A method as claimed in claim 11 wherein step (a) comprises melting the electrically conductive material onto the or each exposed portion of the first semiconductor layer.

13. A method as claimed in claim 11 wherein step (a) comprises heating the wafer to a temperature greater than the melting temperature of the electrically conductive material.

14. A method as claimed in claim 11 wherein step (a) comprises depositing the electrically conductive material on the or each exposed portion of the first semiconductor layer and applying heat to the deposited electrically conductive material thereby to melt the deposited electrically conductive material.

15. A method as claimed in claim 1 comprising the step of annealing the wafer after step (a) and before step (b).

16. A method as claimed in claim 11 comprising the step of annealing the wafer after step (a) and before step (b).

17. A method as claimed claim 1 wherein the electrically conductive material is a metal.

18. A method as claimed in claim 11 wherein the electrically conductive material is a metal.

19. A method as claimed in claim 17 wherein the electrically conductive material is indium.

20. A method as claimed in claim 18 wherein the electrically conductive material is indium.

21. A method as claimed in claim 1 and comprising the further step of providing a plurality of contacts to the second semiconductor layer on the wafer such that each light-emitting device obtained in step (b) comprises a respective one of the contacts to the second semiconductor layer.

22. A method as claimed in claim 11 and comprising the further step of providing a plurality of contacts to the second semiconductor layer on the wafer such that each light-emitting device obtained in step (b) comprises a respective one of the contacts to the second semiconductor layer.

23. A method as claimed in claim 21 wherein the step of forming the plurality of contacts to the second semiconductor layer is carried out before step (a).

24. A method as claimed in claim 22 wherein the step of forming the plurality of contacts to the second semiconductor layer is carried out before step (a).

25. A method as claimed in claim 1 and comprising the step of fabricating the semiconductor wafer by depositing a semiconductor layer structure over a substrate, the layer structure including at least a first semiconductor layer having a first conductivity type and a second semiconductor layer having a second conductivity type different from the first conductivity type.

26. A method as claimed in claim 11 and comprising the step of fabricating the semiconductor wafer by depositing a semiconductor layer structure over a substrate, the layer structure including at least a first semiconductor layer having a first conductivity type and a second semiconductor layer having a second conductivity type different from the first conductivity type.

27. A method as claimed in claim 1 wherein the first semiconductor layer is a (Al,Ga,In)N layer.

28. A method as claimed in claim 1 wherein the second semiconductor layer is a (Al,Ga,In)N layer.

29. A method as claimed in claim 1 wherein the substrate is a sapphire substrate.

30. A method as claimed in claim 11 wherein the first semiconductor layer is a (Al,Ga,In)N layer.

31. A method as claimed in claim 11 wherein the second semiconductor layer is a (Al,Ga,In)N layer.

32. A method as claimed in claim 11 wherein the substrate is a sapphire substrate.

33. A semiconductor light-emitting device manufactured by a method as defined in claim 1.

34. A semiconductor light-emitting device manufactured by a method as defined in claim 11.

35. A method as claimed in claim 6 wherein the electrically conductive material has a melting point of 350° C. or below.

36. A method as claimed in claim 11 wherein the electrically conductive material has a melting point of 350° C. or below.
